(19) United States
(12) Patent Application Publication
(10) Pub. No.: US 2026/0282367 A1
(43) Pub. Date: Sep. 17, 2026

(54) SEMICONDUCTOR DEVICE AND METHOD FOR MANUFACTURING THE SAME

(71) Applicant: Kioxia Corporation, Tokyo (JP)

(72) Inventors: Kenta UEFUJI, Yokkaichi Mie (JP); Daisuke IKENO, Yokkaichi Mie (JP); Mitsuo IKEDA, Tokyo (JP)

(73) Assignee: Kioxia Corporation, Tokyo (JP)

(21) Appl. No.: 19/244,699

(22) Filed: Jun. 20, 2025

(30) Foreign Application Priority Data
Mar. 17, 2025 (JP) 2025-042230

(51) Int. Cl. H10B 43/35; H10B 43/27

(52) U.S. Cl. CPC H10B 43/35; H10B 43/27

(57) ABSTRACT

A semiconductor device includes: a stacked body including a first insulating layer, a conductive layer containing molybdenum, and a second insulating layer; a semiconductor film; a tunnel insulating film; a charge storage film; a first block insulating film provided between the stacked body and the charge storage film, the first block insulating film containing silicon oxide; a second block insulating film provided between the first insulating layer and the conductive layer, between the conductive layer and the second insulating layer, and between the first block insulating film and the conductive layer, and containing aluminum oxide; a first barrier metal film provided between the conductive layer and the second block insulating film, and the first barrier metal film containing silicon, titanium, and nitrogen; and a second barrier metal film provided between the conductive layer and the first barrier metal film, and the second barrier metal film containing titanium and nitrogen.

### CROSS-REFERENCE TO RELATED APPLICATION

This application is based upon and claims the benefit of priority from Japanese Patent Application No. 2025-042230, filed on Mar. 17, 2025, the entire contents of which are incorporated herein by reference.

### FIELD

Embodiments described herein relate generally to a semiconductor memory device and a method for manufacturing the same.

### BACKGROUND

A large-capacity non-volatile memory has been developed. This large-capacity non-volatile memory enables low-voltage and low-current operations, high-speed switching, and miniaturization and high integration of memory cells.

Many metal wirings called bit lines and word lines are arranged in a memory cell array provided in the large-capacity non-volatile memory. A voltage is applied to the bit line and the word line connected to the cell, and data is written into one memory cell corresponding to the bit line and the word line. A semiconductor memory device has been proposed which includes a stacked body, in which a conductive layer serving as a word line and an insulating layer are alternately stacked, and in which memory cells are arranged in a three-dimensional manner.

### BRIEF DESCRIPTION OF THE DRAWINGS

FIG. 1 is a block diagram of a semiconductor memory device of embodiments;

FIG. 2 is an equivalent circuit diagram of the semiconductor memory device of embodiments;

FIG. 3 is a schematic cross-sectional view of a part of the semiconductor memory device of embodiments;

FIG. 4 is a schematic cross-sectional view of another example of a part of the semiconductor memory device of embodiments;

FIG. 5 is a schematic cross-sectional view showing a method for manufacturing a semiconductor memory device of embodiments;

FIG. 6 is a schematic cross-sectional view showing a method for manufacturing a semiconductor memory device of embodiments;

FIG. 7 is a diagram for explaining an example of a method for manufacturing a TiSiN film used as a barrier metal film in the semiconductor memory device of embodiments;

FIG. 8 is a graph showing a change in equivalent oxide thickness according to the ratio of the number of silicon atoms to the sum of the number of silicon atoms and the number of titanium atoms in a semiconductor memory device, which does not include a second barrier metal film but includes a first barrier metal film, and a semiconductor memory device of embodiments, which includes a first barrier metal film and a second barrier metal film; and

FIG. 9 is a graph showing a change in the amount of data retention (DR) degradation in the first barrier metal film according to the ratio of the number of silicon atoms to the sum of the number of silicon atoms and the number of titanium atoms.

### DETAILED DESCRIPTION

A semiconductor memory device of embodiments includes: a stacked body including a first insulating layer, a conductive layer containing molybdenum, and a second insulating layer sequentially stacked in a first direction; a semiconductor film provided separately from the stacked body, and the semiconductor film extending in the first direction; a tunnel insulating film provided between the stacked body and the semiconductor film, and the tunnel insulating film extending in the first direction; a charge storage film provided between the stacked body and the tunnel insulating film, and the charge storage film extending in the first direction; a first block insulating film provided between the stacked body and the charge storage film, the first block insulating film containing silicon oxide, and the first block insulating film extending in the first direction; a second block insulating film provided between the first insulating layer and the conductive layer, the second block insulating film being provided between the conductive layer and the second insulating layer, the second block insulating film being provided between the first block insulating film and the conductive layer, and the second block insulating film containing aluminum oxide; a first barrier metal film provided between the conductive layer and the second block insulating film, and the first barrier metal film containing silicon, titanium, and nitrogen; and a second barrier metal film provided between the conductive layer and the first barrier metal film, and the second barrier metal film containing titanium and nitrogen.

Hereinafter, embodiments will be described with reference to the diagrams. In addition, in the diagrams, the same or similar elements are denoted by the same or similar reference numerals.

In this specification, in order to show the positional relationship of components and the like, the upper direction of the diagram is described as "upper" and the lower direction of the diagram is described as "lower". In this specification, the concepts of "upper" and "lower" do not necessarily indicate the relationship with the direction of gravity.

### Embodiments

A semiconductor memory device of embodiments includes: a stacked body including a first insulating layer, a conductive layer containing molybdenum, and a second insulating layer sequentially stacked in a first direction; a semiconductor film provided separately from the stacked body, and the semiconductor film extending in the first direction; a tunnel insulating film provided between the stacked body and the semiconductor film, and the tunnel insulating film extending in the first direction; a charge storage film provided between the stacked body and the tunnel insulating film, and the charge storage film extending in the first direction; a first block insulating film provided between the stacked body and the charge storage film, the first block insulating film containing silicon oxide, and the first block insulating film extending in the first direction; a second block insulating film provided between the first insulating layer and the conductive layer, the second block insulating film being provided between the conductive layer and the second insulating layer, the second block insulating film being provided between the first block insulating film and the conductive layer, and the second block insulating film containing aluminum oxide; a first barrier metal film provided between the conductive layer and the second block insulating film, and the first barrier metal film containing silicon, titanium, and nitrogen; and a second barrier metal film provided between the conductive layer and the first barrier metal film, and the second barrier metal film containing titanium and nitrogen.

In addition, a semiconductor memory device of embodiments includes: a stacked body including a first insulating layer, a conductive layer containing molybdenum, and a second insulating layer sequentially stacked in a first direction; a semiconductor film provided separately from the stacked body, and the semiconductor film extending in the first direction; a tunnel insulating film provided between the stacked body and the semiconductor film, and the tunnel insulating film extending in the first direction; a charge storage film provided between the stacked body and the tunnel insulating film, and the charge storage film extending in the first direction; a first block insulating film provided between the stacked body and the charge storage film, the first block insulating film containing silicon oxide, and the first block insulating film extending in the first direction; a second block insulating film provided between the first insulating layer and the conductive layer, the second block insulating film being provided between the conductive layer and the second insulating layer, and the second block insulating film being provided between the first block insulating film and the conductive layer, and the second block insulating film containing aluminum oxide; a first barrier metal film provided between the conductive layer and the second block insulating film, the first barrier metal film containing silicon, titanium, and nitrogen, and a ratio of the number of silicon atoms to a sum of the number of silicon atoms and the number of titanium atoms being equal to or more than 40 at% and equal to or less than 80 at%; and a second barrier metal film provided between the conductive layer and the first barrier metal film, and the second barrier metal film containing titanium and nitrogen.

In addition, a semiconductor memory device of embodiments includes: a stacked body including a first insulating layer, a conductive layer containing molybdenum, and a second insulating layer sequentially stacked in a first direction; a semiconductor film provided separately from the stacked body, and the semiconductor film extending in the first direction; a tunnel insulating film provided between the stacked body and the semiconductor film, and the tunnel insulating film extending in the first direction; a charge storage film provided between the stacked body and the tunnel insulating film, and the charge storage film extending in the first direction; a first block insulating film provided between the stacked body and the charge storage film, the first block insulating film containing silicon oxide, and the first block insulating film extending in the first direction; a second block insulating film provided between the first insulating layer and the conductive layer, the second block insulating film being provided between the conductive layer and the second insulating layer, the second block insulating film being provided between the first block insulating film and the conductive layer, and the second block insulating film containing aluminum oxide; and a barrier metal film provided between the conductive layer and the second block insulating film, the barrier metal film including a first region and a second region, the first region containing silicon, titanium, and nitrogen, the second region being provided between the first region and the conductive layer, and the second region having a lower ratio of the number of silicon atoms than the first region.

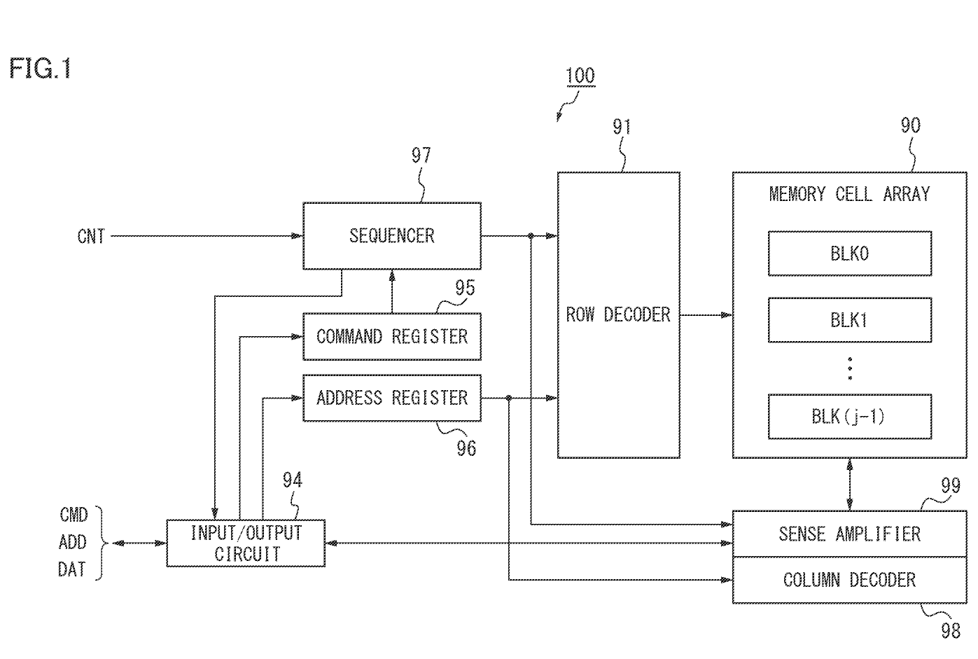

The overall configuration of a semiconductor memory device 100 will be described. The semiconductor memory device 100 of embodiments is a NAND flash memory capable of storing data in a non-volatile manner. FIG. 1 is a block diagram of the semiconductor memory device 100 of embodiments. In addition, the semiconductor memory device 100 of embodiments is an example of a semiconductor device including a logic semiconductor device and the like.

The semiconductor memory device 100 includes a memory cell array 90, a row decoder 91, a column decoder 98, a sense amplifier 99, an input/output circuit 94, a command register 95, an address register 96, and a sequencer (control circuit) 97.

The memory cell array 90 includes j blocks BLK0 to BLK(j-1). j is an integer of 1 or more. Each of the plurality of blocks BLK includes a plurality of memory cell transistors. The memory cell transistor includes an electrically rewritable memory cell. The memory cell array 90 includes a plurality of bit lines, a plurality of word lines, a source line, and the like, in order to control the voltage applied to the memory cell transistors. The specific configuration of each block BLK will be described later.

The row decoder 91 receives a row address from the address register 96 and decodes the row address. The row decoder 91 selects a word line or the like based on the decoded row address. Then, the row decoder 91 transfers a plurality of voltages required for a write operation, a read operation, and an erase operation to the memory cell array 90.

The column decoder 98 receives a column address from the address register 96 and decodes the column address. The column decoder 98 selects a bit line based on the decoded column address.

During a read operation, the sense amplifier 99 detects and amplifies data read from the memory cell transistor to the bit line. In addition, during a write operation, the sense amplifier 99 transfers write data to the bit line.

The input/output circuit 94 is connected to an external device (host device) through a plurality of input/output lines (DQ lines). The input/output circuit 94 receives a command CMD and an address ADD from the external device. The command CMD received by the input/output circuit 94 is transmitted to the command register 95. The address ADD received by the input/output circuit 94 is transmitted to the address register 96. In addition, the input/output circuit 94 transmits and receives data DAT to and from the external device.

The sequencer 97 receives a control signal CNT from the external device. The control signal CNT includes a chip enable signal CEn, a command latch enable signal CLE, an address latch enable signal ALE, a write enable signal WEn, and a read enable signal REn. The "n" added to the signal name indicates active low. The sequencer 97 controls the overall operation of the semiconductor memory device 100 based on the command CMD held in the command register 95 and the control signal CNT.

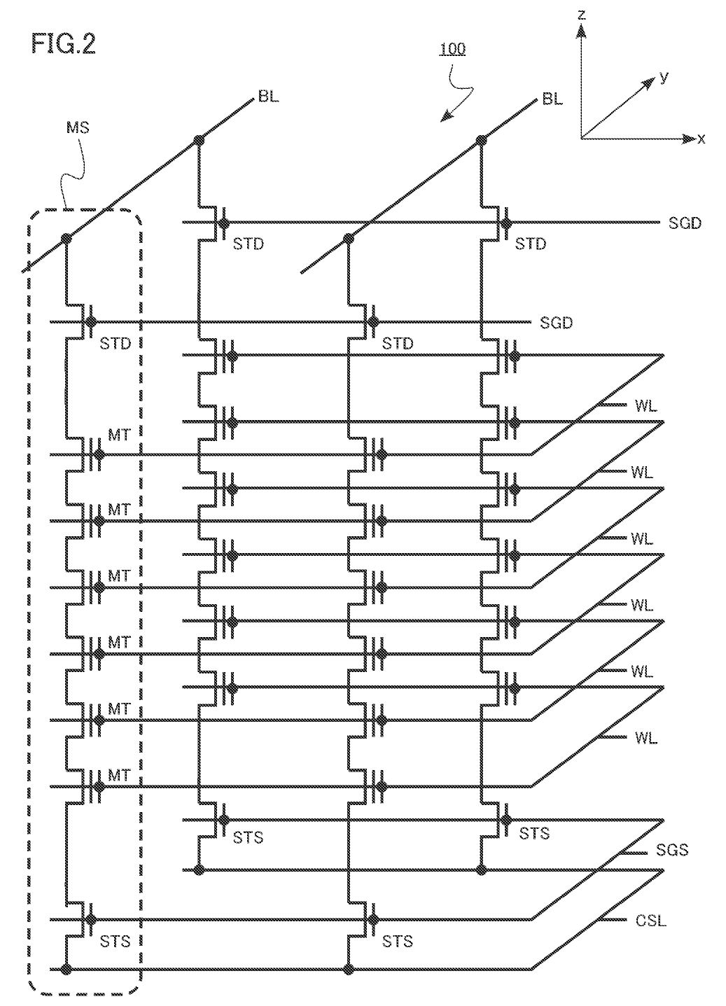

FIG. 2 is an equivalent circuit diagram of the semiconductor memory device 100 of embodiments.

As shown in FIG. 2, the semiconductor memory device 100 includes a plurality of word lines WL, a common source line CSL, a source selection gate line SGS, a plurality of drain selection gate lines SGD, a plurality of bit lines BL, and a plurality of memory strings MS.

The memory string MS has a source selection transistor STS, a plurality of memory cell transistors MT, and a drain selection transistor STD, which are connected in series between the common source line CSL and the bit line BL.

In addition, the number of word lines WL, the number of bit lines BL, the number of memory strings MS, and the number of drain selection gate lines SGD are not limited to those shown in FIG. 2.

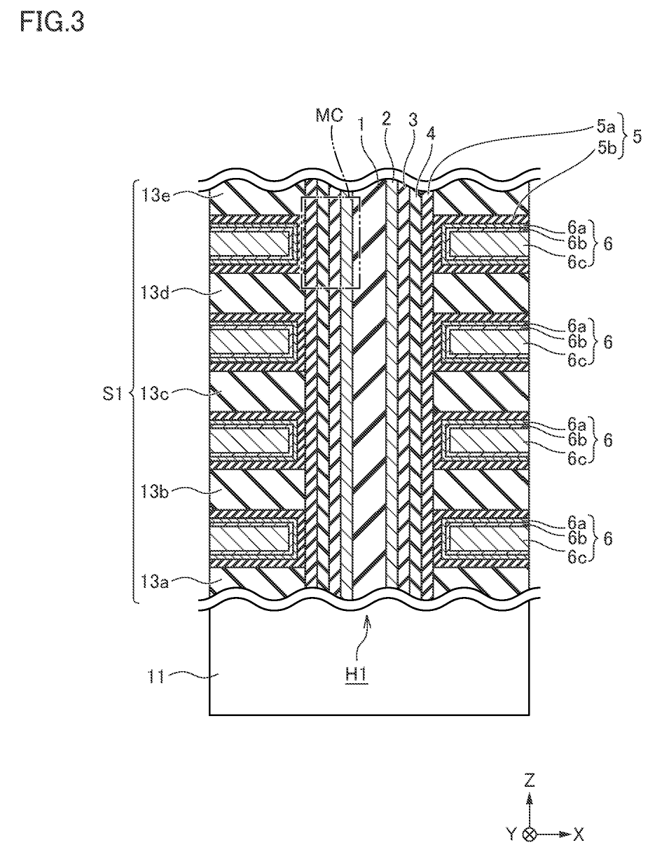

FIG. 3 is a schematic cross-sectional view of a part of the semiconductor memory device of embodiments.

A substrate 11 is, for example, a semiconductor layer containing single crystal silicon (Si). The substrate 11 can be, for example, a semiconductor wafer or an SOI wafer.

Here, an X direction, a Y direction perpendicular to the X direction, and a Z direction perpendicular to the X and Y directions are defined. The substrate 11 is provided in parallel to the XY plane. In addition, the Z direction is an example of the first direction.

On the substrate 11, a plurality of insulating layers 13 containing oxide and a conductive layer 6c are alternately stacked one by one in the Z direction. For example, the plurality of insulating layers 13 are a first insulating layer 13a, a second insulating layer 13b, a third insulating layer 13c, a fourth insulating layer 13d, and a fifth insulating layer 13e. In this manner, a stacked body S1 is provided on the substrate 11. Here, the oxide is, for example, a silicon oxide.

A memory pillar H1 penetrates the stacked body S1 in the Z direction. In the memory pillar H1, a core insulating film 1, a channel semiconductor layer (an example of a semiconductor film) 2, a tunnel insulating film 3, a charge storage film 4, and a first block insulating film 5a are provided. The core insulating film 1, the channel semiconductor layer 2, the tunnel insulating film 3, the charge storage film 4, and the first block insulating film 5a each extend in the Z direction.

The core insulating film 1 is provided in the memory pillar H1 so as to be spaced from the stacked body S1. The core insulating film 1 contains, for example, silicon oxide.

The channel semiconductor layer 2 is provided around the core insulating film 1 in the memory pillar H1. The channel semiconductor layer 2 is provided so as to be spaced from the stacked body S1. The channel semiconductor layer 2 functions as a channel of the memory pillar H1. The channel semiconductor layer 2 is, for example, a pillar containing a semiconductor material such as polysilicon.

The tunnel insulating film 3 is provided around the channel semiconductor layer 2 in the memory pillar H1. The tunnel insulating film 3 is provided between the stacked body S1 and the channel semiconductor layer 2. The tunnel insulating film 3 is an insulating film that is insulating but allows a current to flow when a predetermined voltage is applied. The tunnel insulating film 3 is, for example, a pillar containing silicon oxynitride.

The charge storage film 4 is provided around the tunnel insulating film 3 in the memory pillar H1. The charge storage film 4 is provided between the stacked body S1 and the tunnel insulating film 3. The charge storage film 4 is a film containing a material capable of storing charges. The charge storage film 4 is, for example, a pillar containing silicon nitride.

The first block insulating film 5a is provided around the charge storage film 4 in the memory pillar H1. The first block insulating film 5a is provided between the stacked body S1 and the charge storage film 4. The first block insulating film 5a is, for example, a pillar containing silicon oxide.

A second block insulating film 5b, a first barrier metal film 6a, a second barrier metal film 6b, and the conductive layer 6c are provided between the insulating layers 13 adjacent to each other in the Z direction.

The second block insulating film 5b is provided between the insulating layer 13 (for example, the first insulating layer 13a) adjacent to the conductive layer 6c on the lower side and the conductive layer 6c, between the insulating layer 13 (for example, the second insulating layer 13b) adjacent to the conductive layer 6c on the upper side and the conductive layer 6c, and between the first block insulating film 5a and the conductive layer 6c. The second block insulating film 5b is provided on the upper surface of the insulating layer 13 adjacent to the lower side, the lower surface of the insulating layer 13 adjacent to the upper side, and the side surface of the first block insulating film 5a. The second block insulating film 5b contains a metal insulating material such as aluminum oxide.

The first barrier metal film 6a is provided between the conductive layer 6c and the second block insulating film 5b. The first barrier metal film 6a is provided on the upper surface of the second block insulating film 5b on the lower side, the lower surface of the second block insulating film 5b on the upper side, and the side surface of the second block insulating film 5b provided on the side surface of the first block insulating film 5a. The first barrier metal film 6a contains silicon, titanium (Ti), and nitrogen (N). The first barrier metal film 6a is, for example, a TiSiN film.

The second barrier metal film 6b is provided between the conductive layer 6c and the first barrier metal film 6a. The second barrier metal film 6b is provided on the upper surface of the first barrier metal film 6a on the lower side, the lower surface of the first barrier metal film 6a on the upper side, and the side surface of the first barrier metal film 6a provided on the side surface of the second block insulating film 5b provided on the side surface of the first block insulating film 5a. The second barrier metal film 6b contains titanium and nitrogen. The second barrier metal film 6b is, for example, a titanium nitride (TiN) film.

The conductive layer 6c is provided in the second barrier metal film 6b. The conductive layer 6c corresponds to the word line WL. The conductive layer 6c contains molybdenum (Mo). In addition, holes (not shown) may be formed in the conductive layer 6c during the manufacturing of the conductive layer 6c.

A memory cell MC is provided in each portion of the memory pillar H1 facing the conductive layer 6c. A plurality of memory cells MC provided in one memory pillar H1 are included in one memory string MS. Each memory cell MC includes a memory cell transistor MT.

In addition, FIG. 3 shows one memory string MS among the memory strings MS shown in FIG. 2. The semiconductor memory device 100 includes a plurality of memory pillars H1.

In addition, for example, the common source line CSL, the source selection gate line SGS, and a plurality of source selection transistors STS (all of which are not shown) are provided between the stacked body S1 and the substrate 11.

In addition, for example, a plurality of drain selection gate lines SGD, a plurality of bit lines BL, and a plurality of drain selection transistors STD (all of which are not shown) are provided on the stacked body S1.

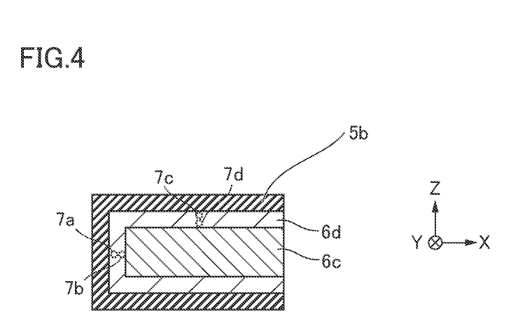

FIG. 4 is a schematic cross-sectional view showing another example of a part of the semiconductor memory device of embodiments.

A first region 7a and a second region 7b provided between the first region 7a and the conductive layer 6c are provided in the barrier metal film 6d. The first region 7a contains silicon, titanium, and nitrogen. The ratio of the number of silicon atoms in the second region 7b is lower than that in the first region 7a.

In addition, a third region 7c and a fourth region 7d provided between the third region 7c and the conductive layer 6c are provided in the barrier metal film 6d. The third region 7c contains silicon, titanium, and nitrogen. The ratio of the number of silicon atoms in the fourth region 7d is lower than that in the third region 7c. Here, the third region 7c is an example of the first region. The fourth region 7d is an example of the second region.

For example, the first region 7a and the third region 7c correspond to the first barrier metal film 6a (FIG. 3). For example, the second region 7b and the fourth region 7d correspond to the second barrier metal film 6b (FIG. 3).

In addition, elements contained in the first barrier metal film 6a, the second barrier metal film 6b, the first region 7a, the second region 7b, the third region 7c, and the fourth region 7d can be analyzed by, for example, energy dispersive X-ray spectroscopy (EDX).

In the first barrier metal film 6a, the ratio of the number of silicon atoms to the sum of the number of silicon atoms and the number of titanium atoms is preferably equal to or more than 40at%. In addition, in the first barrier metal film 6a, the ratio of the number of silicon atoms to the sum of the number of silicon atoms and the number of titanium atoms is preferably equal to or less than 80at%.

In addition, when the ratio of the number of silicon atoms to the sum of the number of silicon atoms and the number of titanium atoms is less than 40 at%, the first barrier metal film 6a is crystalline. On the other hand, when the ratio of the number of silicon atoms to the sum of the number of silicon atoms and the number of titanium atoms is equal to or more than 40at%, the first barrier metal film 6a is non-crystalline (amorphous).

The semiconductor memory device of embodiments can be more preferably implemented when the conductive layer 6c contains oxygen (O).

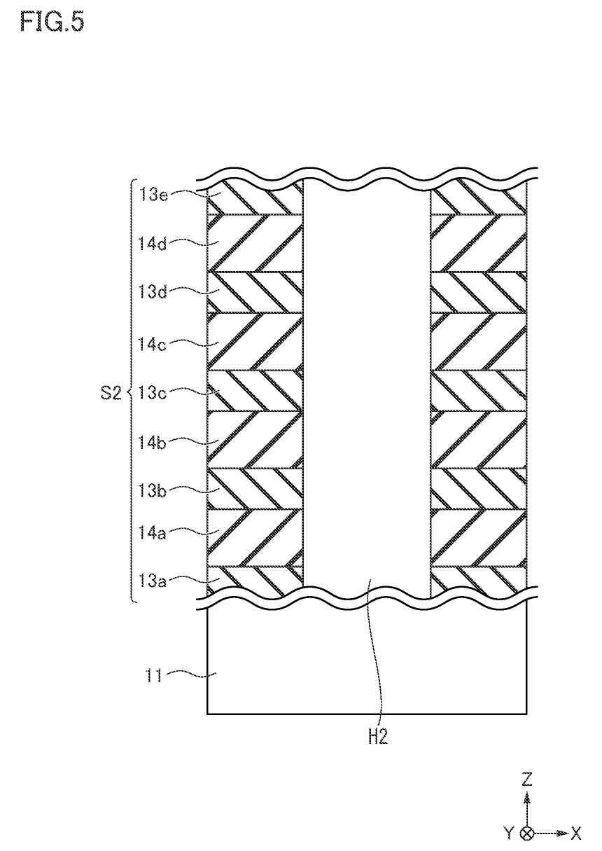

FIGS. 5-7 are schematic cross-sectional views showing a method for manufacturing a semiconductor memory device of embodiments. The method for manufacturing a semiconductor device of embodiments includes: forming a stacked film, a first insulating layer, a sacrificial layer containing nitride, and a second insulating layer being alternately stacked one by one in a first direction; forming an opening penetrating the stacked film and extending in the first direction; forming a first block insulating film, a charge storage film, a tunnel insulating film, a channel semiconductor layer, and a core insulating film sequentially in the opening; removing the sacrificial layer; and forming, in a portion where the sacrificial layer has been removed, a second block insulating film, a first barrier metal film containing nitrogen, titanium, and silicon, a second barrier metal film containing titanium and nitrogen, and a conductive layer containing molybdenum in a sequential manner. The first barrier metal film is formed so that the ratio of the number of silicon atoms to the sum of the number of silicon atoms and the number of titanium atoms in the first barrier metal film is equal to or more than 40 at% by controlling a ratio between the number of times a first film containing nitrogen and silicon is manufactured and the number of times a second film containing nitrogen and titanium is manufactured. Here, the second block insulating film is formed, for example, on a surface of the first insulating layer facing the second insulating layer, a surface of the second insulating layer facing the first insulating layer, and a surface of the first block insulating film opposite to the charge storage film. In addition, the first barrier metal film is formed, for example, on a surface of the second block insulating film opposite to the first insulating layer, the second insulating layer, and the first block insulating film. In addition, the second barrier metal film is formed, for example, on a surface of the first barrier metal film opposite to the second block insulating film. In addition, a conductive layer containing molybdenum is formed, for example, on a surface of the second barrier metal film opposite to the first barrier metal film.

The common source line CSL, the source selection gate line SGS, and a plurality of source selection transistors STS (all of which are not shown) are formed on the substrate 11.

Then, a plurality of insulating layers 13 containing oxide and a plurality of sacrificial layers 14 containing nitride are formed so as to be alternately stacked one by one in the Z direction using, for example, a chemical vapor deposition (CVD) method. As a result, a stacked body S2 is formed. Here, the oxide is, for example, a silicon oxide. In addition, the nitride is, for example, a silicon nitride. Then, an opening H2 (through hole) penetrating the stacked body S2 in the Z direction and extending in the Z direction is formed by using, for example, a reactive ion etching (RIE) method (FIG. 5).

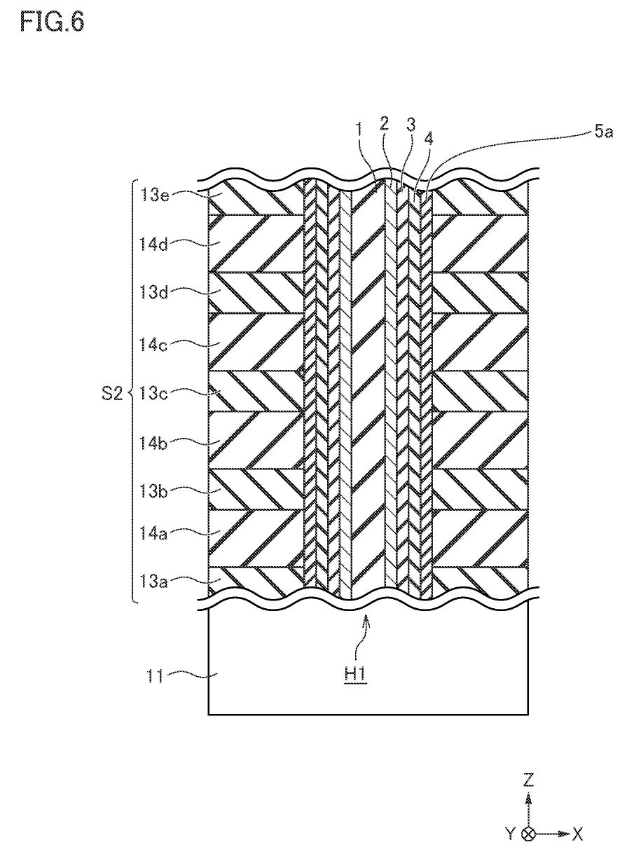

Then, the first block insulating film 5a, the charge storage film 4, the tunnel insulating film 3, and a part of the channel semiconductor layer 2 are sequentially formed in the opening H2 by using, for example, an atomic layer deposition (ALD) method. Then, the first block insulating film 5a, the charge storage film 4, the tunnel insulating film 3, and a part of the channel semiconductor layer 2 are removed from the bottom of the opening H2 by, for example, etching. Then, the remaining part of the channel semiconductor layer 2 and the core insulating film 1 are sequentially formed in the opening H2 by using, for example, an ALD method. As a result, the first block insulating film 5a, the charge storage film 4, the tunnel insulating film 3, the channel semiconductor layer 2, and the core insulating film 1 are sequentially formed in the opening H2 (FIG. 6).

Then, a slit (not shown) is formed in the stacked body S1. Then, a chemical solution such as phosphoric acid is supplied using the slit to remove the plurality of sacrificial layers 14. Then, the second block insulating film 5b, the first barrier metal film 6a, the second barrier metal film 6b, and the conductive layer 6c are sequentially formed in a portion where the plurality of sacrificial layers 14 have been removed. As a result, the stacked body S2 is formed.

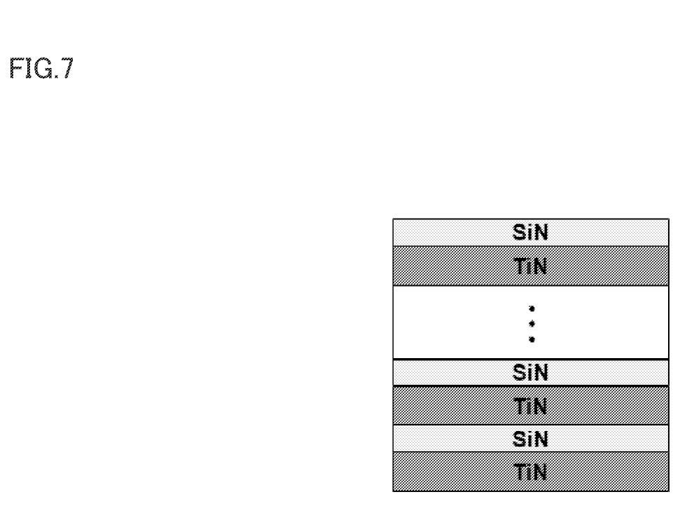

FIG. 7 is a diagram for explaining an example of a method for manufacturing a TiSiN film used as a barrier metal film in the semiconductor memory device of embodiments. A silicon nitride (SiN) film containing nitrogen and silicon is manufactured by, for example, a CVD method (including an ALD method, which is one type of CVD method) using dichlorosilane (DCS) and ammonia (NH₃) as raw materials. In addition, a titanium nitride (TiN) film containing nitrogen and titanium is manufactured by a reaction using a CVD method (including an ALD method, which is one type of CVD method) using titanium tetrachloride (TiCl₄) and ammonia. Here, the silicon nitride film is an example of the first film. In addition, the titanium nitride film is an example of the second film. The TiSiN film used as a barrier metal film is a TiSiN film containing Ti, Si, and N as a whole. However, when viewed in detail, the TiSiN film used as a barrier metal film has a stacked structure of a silicon nitride film and a titanium nitride film, as shown in FIG. 7. For example, by controlling the ratio (cycle ratio) of the number of times the silicon nitride film is manufactured and the number of times the titanium nitride film is manufactured, the ratio of titanium, silicon, and nitrogen in the first barrier metal film 6a can be controlled. For example, by increasing the ratio of the number of times the silicon nitride film is manufactured (cycle ratio) or the manufacturing rate of the silicon nitride film, the proportion of silicon in the first barrier metal film 6a can be increased to 40 at% or more. In addition, the method for manufacturing a barrier metal film is not limited to the above.

The conductive layer 6c is manufactured by, for example, a CVD method (including an ALD method, which is one type of CVD method) using molybdenum dichloride (MoO₂Cl₂) and hydrogen (H₂) as raw materials.

Then, a plurality of drain selection gate lines SGD, a plurality of bit lines BL, and a plurality of drain selection transistors STD (all of which are not shown) are formed on the stacked body S2. In this manner, the semiconductor memory device 100 of embodiments is obtained.

Next, the function and effect of the semiconductor memory device of embodiments will be described.

For the purpose of lowering the resistance of the word line WL and obtaining the word line WL not containing fluorine (F), the introduction of the word line WL containing molybdenum is considered. Here, when a film containing one layer of titanium and nitrogen is used as a barrier metal film for the word line WL containing molybdenum, for example, data retention (DR) degradation becomes a problem that is caused by the diffusion of oxygen into the first block insulating film 5a due to molybdenum dichloride used as a raw material and the diffusion of hydrogen entering from the outside the semiconductor memory device into the first block insulating film 5a.

Then, when a film containing one layer of titanium, silicon, and nitrogen is used as a barrier metal film for the word line WL containing molybdenum, the diffusion of oxygen and hydrogen into the first block insulating film 5a is suppressed. Therefore, the DR degradation is suppressed. However, when manufacturing the word line WL containing molybdenum, oxygen caused by molybdenum dichloride reacts with silicon in the barrier metal film, forming a layer containing silicon oxide between the word line WL and the barrier metal film. This increases the equivalent oxide thickness (EOT). For this reason, there has been a problem that the operating voltage of the semiconductor memory device becomes high.

Therefore, the semiconductor memory device of embodiments includes: a stacked body including a first insulating layer, a conductive layer containing molybdenum, and a second insulating layer sequentially stacked in a first direction; a semiconductor film provided separately from the stacked body, and the semiconductor film extending in the first direction; a tunnel insulating film provided between the stacked body and the semiconductor film, and the tunnel insulating film extending in the first direction; a charge storage film provided between the stacked body and the tunnel insulating film, and the charge storage film extending in the first direction; a first block insulating film provided between the stacked body and the charge storage film, the first block insulating film containing silicon oxide, and the first block insulating film extending in the first direction; a second block insulating film provided between the first insulating layer and the conductive layer, the second block insulating film being provided between the conductive layer and the second insulating layer, the second block insulating film being provided between the first block insulating film and the conductive layer, and the second block insulating film containing aluminum oxide; a first barrier metal film provided between the conductive layer and the second block insulating film, and the first barrier metal film containing silicon, titanium, and nitrogen; and a second barrier metal film provided between the conductive layer and the first barrier metal film, and the second barrier metal film containing titanium and nitrogen.

According to this, since the second barrier metal film 6b is provided between the first barrier metal film 6a and the conductive layer 6c, the formation of a layer containing silicon oxide between the word line WL and the barrier metal film is suppressed. In addition, the diffusion of oxygen and hydrogen into the first block insulating film 5a is suppressed by the first barrier metal film 6a. Therefore, it is possible to provide a semiconductor memory device that can suppress an increase in equivalent oxide thickness and obtain good data retention characteristics.

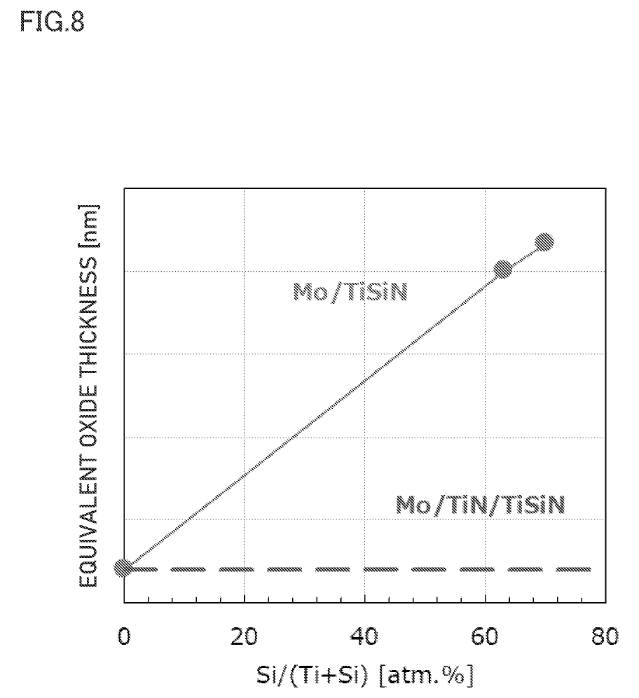

FIG. 8 is a graph showing a change in equivalent oxide thickness according to the ratio of the number of silicon atoms to the sum of the number of silicon atoms and the number of titanium atoms in a semiconductor memory device of a comparative form (denoted as "Mo/TiSiN"), which does not include the second barrier metal film 6b (for example, a titanium nitride (TiN) film) but includes the first barrier metal film 6a (for example, a TiSiN film), and a semiconductor memory device of embodiments (denoted as "Mo/TiN/TiSiN"), which includes the first barrier metal film 6a and the second barrier metal film 6b. For example, FIG. 8 is a graph showing a change in the ratio of the number of silicon atoms to the sum of the number of silicon atoms and the number of titanium atoms in a semiconductor memory device of a comparative form (denoted as "Mo/TiSiN") including a single-layer barrier metal film and a semiconductor memory device of embodiments (denoted as "Mo/TiN/TiSiN") including a multi-layer barrier metal film.

In the case of the semiconductor memory device of the comparative form that does not include the second barrier metal film 6b but includes the first barrier metal film 6a (solid line), the equivalent oxide thickness increases with an increase in the ratio of the number of silicon atoms. This is because the oxygen contained in the conductive layer 6c reacts with the silicon contained in the first barrier metal film 6a and accordingly, a film containing silicon oxide is formed between the first barrier metal film 6a and the conductive layer 6c.

In contrast, in the case of the semiconductor memory device of embodiments including the first barrier metal film 6a and the second barrier metal film 6b (dashed line), even if the ratio of the number of silicon atoms increases, the equivalent oxide thickness does not increase. In other words, in the case of the semiconductor memory device of embodiments, even if the ratio of the number of silicon atoms increases, an increase in equivalent oxide thickness is suppressed. This is because the ratio of the number of silicon atoms in the second barrier metal film 6b is lower than that in the first barrier metal film 6a and accordingly, the formation of a film containing silicon oxide is suppressed.

In the first barrier metal film 6a, the ratio of the number of silicon atoms to the sum of the number of silicon atoms and the number of titanium atoms is preferably equal to or more than 40 at%. In addition, in the first barrier metal film 6a, the ratio of the number of silicon atoms to the sum of the number of silicon atoms and the number of titanium atoms is preferably equal to or less than 80 at%.

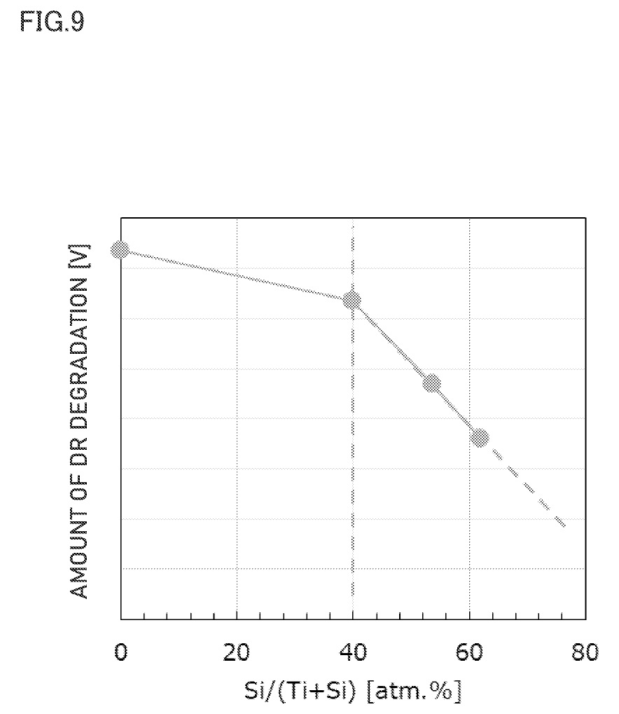

FIG. 9 is a graph showing a change in the amount of data retention (DR) degradation in the first barrier metal film 6a according to the ratio (Si/(Ti+Si) [at%]) of the number of silicon atoms to the sum of the number of silicon atoms and the number of titanium atoms. Here, the amount of data retention degradation is, for example, the amount of degradation in the data retention characteristics when comparing a predetermined point in time after the manufacture of a semiconductor memory device with a point in time after a predetermined period of time has passed from the predetermined point in time.

The amount of data retention degradation decreases as the ratio of the number of silicon atoms increases. When the ratio of the number of silicon atoms is equal to or more than 40 at%, the rate of decrease in the amount of data retention degradation increases, and the tendency for the amount of data retention degradation to decrease becomes stronger. Therefore, in the first barrier metal film 6a, the ratio of the number of silicon atoms to the sum of the number of silicon atoms and the number of titanium atoms is preferably equal to or more than 40 at%. In addition, when the ratio of the number of silicon atoms to the sum of the number of silicon atoms and the number of titanium atoms in the first barrier metal film 6a exceeds 80 at%, the composition of the first barrier metal film 6a becomes close to silicon nitride, and accordingly, the insulating property of the first barrier metal film 6a becomes high. For this reason, in the first barrier metal film 6a, the ratio of the number of silicon atoms to the sum of the number of silicon atoms and the number of titanium atoms is preferably equal to or less than 80 at%.

The semiconductor memory device of embodiments is particularly effective because the formation of a layer containing silicon oxide between the word line WL and the conductive layer 6c is suppressed when the conductive layer 6c contains oxygen.

According to the semiconductor device of embodiments, it is possible to provide a semiconductor device and a method for manufacturing the same that can suppress an increase in equivalent oxide thickness and obtain good data retention characteristics.

In addition, although embodiments have been described with the semiconductor memory device 100 as an example, embodiments may also be used in a logic semiconductor device. Here, the logic semiconductor device is, for example, a semiconductor device for performing arithmetic processing, such as a central processing unit (CPU), a graphics processing unit (GPU), an application specific integrated circuit (ASIC), and a field programmable gate array (FPGA). For example, embodiment can be applied to a case where a conductive layer included in the wiring in the CPU included in the sequencer 97 contains molybdenum. In addition, for example, embodiments can also be applied to a case where a conductive layer included in the wiring in the GPU, ASIC, or FPGA contains molybdenum.

While certain embodiments have been described, these embodiments have been presented by way of example only, and are not intended to limit the scope of the inventions. Indeed, the semiconductor memory device and the method for manufacturing the same described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a stacked body including a first insulating layer, a first conductive layer containing molybdenum, and a second insulating layer sequentially stacked in a first direction;
a semiconductor film provided separately from the stacked body, and the semiconductor film extending in the first direction;
a tunnel insulating film provided between the stacked body and the semiconductor film, and the tunnel insulating film extending in the first direction;
a charge storage film provided between the stacked body and the tunnel insulating film, and the charge storage film extending in the first direction;
a first block insulating film provided between the stacked body and the charge storage film, the first block insulating film containing silicon oxide, and the first block insulating film extending in the first direction;
a second block insulating film provided between the first insulating layer and the first conductive layer, the second block insulating film being provided between the first conductive layer and the second insulating layer, the second block insulating film being provided between the first block insulating film and the first conductive layer, and the second block insulating film containing aluminum oxide;
a first barrier metal film provided between the first conductive layer and the second block insulating film, and the first barrier metal film containing silicon, titanium, and nitrogen; and
a second barrier metal film provided between the first conductive layer and the first barrier metal film, and the second barrier metal film containing titanium and nitrogen.

2. The semiconductor device according to claim 1,
wherein, in the first barrier metal film, a ratio of the number of silicon atoms to a sum of the number of silicon atoms and the number of titanium atoms is equal to or more than 40 at%.

3. The semiconductor device according to claim 2,
wherein, in the first barrier metal film, the ratio of the number of silicon atoms to the sum of the number of silicon atoms and the number of titanium atoms is equal to or less than 80 at%.

4. The semiconductor device according to claim 1,
wherein the first conductive layer further contains oxygen.

5. The semiconductor device according to claim 1, further comprising:
the stacked body including the first insulating layer, the first conductive layer containing molybdenum, the second insulating layer, the second conductive layer containing molybdenum, and the third insulating layer sequentially stacked in the first direction;
a third block insulating film provided between the second insulating layer and the second conductive layer, the third block insulating film being provided between the second conductive layer and the third insulating layer, the third block insulating film being provided between the first block insulating film and the second conductive layer, and the third block insulating film containing aluminum oxide;
a third barrier metal film provided between the second conductive layer and the third block insulating film, and the third barrier metal film containing silicon, titanium, and nitrogen; and
a fourth barrier metal film provided between the second conductive layer and the third barrier metal film, and the fourth barrier metal film containing titanium and nitrogen.

6. The semiconductor device according to claim 1,
wherein the semiconductor device is a semiconductor memory device or a logic semiconductor device.

7. The semiconductor device according to claim 1,
wherein the first barrier metal is amorphous.

8. A semiconductor device, comprising:
a stacked body including a first insulating layer, a first conductive layer containing molybdenum, and a second insulating layer sequentially stacked in a first direction;
a semiconductor film provided separately from the stacked body, and the semiconductor film extending in the first direction;
a tunnel insulating film provided between the stacked body and the semiconductor film, and the tunnel insulating film extending in the first direction;
a charge storage film provided between the stacked body and the tunnel insulating film, and the charge storage film extending in the first direction;
a first block insulating film provided between the stacked body and the charge storage film, the first block insulating film containing silicon oxide, and the first block insulating film extending in the first direction;
a second block insulating film provided between the first insulating layer and the first conductive layer, the second block insulating film being provided between the first conductive layer and the second insulating layer, the second block insulating film being provided between the first block insulating film and the first conductive layer, and the second block insulating film containing aluminum oxide; and
a barrier metal film provided between the first conductive layer and the second block insulating film, the barrier metal film including a first region and a second region, the first region containing silicon, titanium, and nitrogen, the second region being provided between the first region and the first conductive layer, and the second region having a lower ratio of the number of silicon atoms than the first region.

9. The semiconductor device according to claim 8,
wherein, in the first region, a ratio of the number of silicon atoms to a sum of the number of silicon atoms and the number of titanium atoms is equal to or more than 40 at%.

10. The semiconductor device according to claim 9,
wherein, in the first region, the ratio of the number of silicon atoms to a sum of the number of silicon atoms and the number of titanium atoms is equal to or less than 80 at%.

11. The semiconductor device according to claim 8,
wherein the first conductive layer further contains oxygen.

12. The semiconductor device according to claim 8,
wherein the semiconductor device is a semiconductor memory device or a logic semiconductor device.

13. The semiconductor device according to claim 8,
wherein the first barrier metal is amorphous.

14. A method for manufacturing a semiconductor device, comprising:
forming a stacked film, and the stacked film including a first insulating layer, a sacrificial layer containing nitride, and a second insulating layer being alternately stacked one by one in a first direction;
forming an opening penetrating the stacked film, and the opening extending in the first direction;
forming a first block insulating film, a charge storage film, a tunnel insulating film, a channel semiconductor layer, and a core insulating film sequentially in the opening;
removing the sacrificial layer; and
forming, in a portion where the sacrificial layer has been removed, a second block insulating film, a first barrier metal film containing nitrogen, titanium, and silicon, a second barrier metal film containing titanium and nitrogen, and a first conductive layer containing molybdenum in a sequential manner,
wherein the first barrier metal film is formed so that a ratio of the number of silicon atoms to a sum of the number of silicon atoms and the number of titanium atoms in the first barrier metal film is equal to or more than 40 at% by controlling a ratio between the number of times a first film containing nitrogen and silicon is manufactured and the number of times a second film containing nitrogen and titanium is manufactured.

15. The method for manufacturing a semiconductor device according to claim 14,
wherein, in the first barrier metal film, the ratio of the number of silicon atoms to the sum of the number of silicon atoms and the number of titanium atoms is equal to or more than 40 at%.

16. The method for manufacturing a semiconductor device according to claim 15,
wherein, in the first barrier metal film, the ratio of the number of silicon atoms to the sum of the number of silicon atoms and the number of titanium atoms is equal to or less than 80 at%.

17. The method for manufacturing a semiconductor device according to claim 14,
wherein the first conductive layer further contains oxygen.

18. The method for manufacturing a semiconductor device according to claim 14,
wherein the semiconductor device is a semiconductor memory device or a logic semiconductor device.

19. The method for manufacturing a semiconductor device according to claim 14,
wherein the first barrier metal is amorphous.

20. The method for manufacturing a semiconductor device according to claim 14,
wherein, controlling the ratio between the number of times is, controlling the ratio (cycle ratio) using a chemical vapor deposition (CVD) method.
